(19) United States
(12) Patent Application Publication
(10) Pub. No.: US 2024/0035192 A1
(43) Pub. Date: Feb. 1, 2024

(54) Polishing Device for Indium Phosphide Substrate, and Polishing Process

(71) Applicant: THE 13TH RESEARCH INSTITUTE OF CHINA ELECTRONICS TECHNOLOGY GROUP CORPORATION, Shijiazhuang, Hebei (CN)

(72) Inventors: Shujie WANG, Shijiazhuang, Hebei (CN); Niefeng SUN, Shijiazhuang, Hebei (CN); Yang WANG, Shijiazhuang, Hebei (CN); Xiaolan LI, Shijiazhuang, Hebei (CN); Yanlei SHI, Shijiazhuang, Hebei (CN); Huimin SHAO, Shijiazhuang, Hebei (CN); Lijie FU, Shijiazhuang, Hebei (CN); Zheng LIU, Shijiazhuang, Hebei (CN); Tongnian SUN, Shijiazhuang, Hebei (CN); Huisheng LIU, Shijiazhuang, Hebei (CN)

(21) Appl. No.: 17/797,395

(22) PCT Filed: Jul. 5, 2021
(86) PCT No.: PCT/CN2021/104413

§ 371 Date: Aug. 3, 2022

(30) Foreign Application Priority Data
Mar. 29, 2021 (CN) 202110331419.5
Mar. 29, 2021 (CN) 202120628422.9

(51) Int. Cl. C25F 7/00; C25F 3/30

(52) U.S. Cl. CPC C25F 7/00; C25F 3/30

(57) ABSTRACT

A polishing device for an indium phosphide substrate and a polishing process are provided, which belong to the technical field of polishing of indium phosphide. The polishing device includes an electrolyzer, and further includes an anode disc supporting rod positioned at a center position of a bottom of the electrolyzer by virtue of an anode lifting mechanism; an anode disc hinged to an upper end of the anode disc supporting rod; a cathode disc supporting rod positioned above the anode disc by virtue of a cathode lifting mechanism; a cathode disc arranged at a lower end of the cathode disc supporting rod; a graphite electrode plate arranged on the anode disc by virtue of a connection mechanism; a group of planet gears arranged on an upper end surface of the graphite electrode plate by virtue of an intermediate driving mechanism; an anode rotation driving mechanism connected to the intermediate driving mechanism; a cathode rotation driving mechanism connected to the cathode disc supporting rod; and a polishing direct current (DC) power supply respectively connected to contacts of the anode disc supporting rod and the cathode disc supporting rod by virtue of wires. By improving the structure of the device and the manufacturing process, a requirement for the environment in the polishing process of indium phosphide is greatly reduced, and electrochemical and mechanical dual-polishing is achieved.

### TECHNICAL FIELD

The present invention belongs to the technical field of polishing of indium phosphide, and specifically relates to a polishing device for an indium phosphide substrate, and a polishing process.

### BACKGROUND ART

An indium phosphide (InP) material is an important III-V compound semiconductor material, and has the characteristics of high electron mobility and high saturation drift rate. The InP material is a main basic material for realizing millimeter-wave circuits and terahertz electronic devices. An InP-based device has the characteristics of high frequency, low noise, high efficiency, radiation resistance, and the like, which is the first choice for bands above 100 GHz, has excellent performance in W-band and higher-frequency millimeter-wave circuits, and is widely applied to optical fiber communication, mobile communication, medical imaging, terahertz communication, and other fields.

The polishing technology for InP is an important indicator to measure its preparation level. A smooth and less rough polishing interface is very important for the subsequent epitaxial growth. Usually, the polishing of an InP single crystal substrate mainly adopts an electrochemical polishing technology or a mechanical polishing technology, but the polishing effects of the two technologies are not stable, and the polishing uniformity is not ideal. Especially, chemical compositions of a polishing solution in the electrochemical polishing technology are complex and have high environment requirements. Therefore, how to achieve an InP polishing technology with low cost and ideal polishing effect has become a problem urgent to be solved.

### SUMMARY OF THE INVENTION

The technical problem to be solved in the present invention is to provide a polishing device for an indium phosphide substrate, and a polishing process. By improving the structure of the device and the process, in combination with the advantages of electrochemical polishing and mechanical polishing technologies, a requirement for the environment in the polishing process of indium phosphide is greatly reduced, and the polishing effect is ideal.

The technical solution adopted in the present invention is as follows: A polishing device for an indium phosphide substrate includes an electrolyzer; the polishing device further includes an anode disc supporting rod positioned at a center position of a bottom of the electrolyzer by virtue of an anode lifting mechanism; an anode disc hinged to an upper end of the anode disc supporting rod; a cathode disc supporting rod positioned above the anode disc by virtue of a cathode lifting mechanism; a cathode disc arranged at a lower end of the cathode disc supporting rod; polishing cloth positioned on a lower end surface of the cathode disc by virtue of a cathode polishing cloth clamp; a graphite electrode plate arranged on the anode disc by virtue of a connection mechanism; a group of planet gears arranged on an upper end surface of the graphite electrode plate by virtue of an intermediate driving mechanism; polishing cloth positioned between the graphite electrode plate and the planet gear by virtue of an anode polishing cloth clamp; an anode rotation driving mechanism connected to the intermediate driving mechanism; a cathode rotation driving mechanism connected to the cathode disc supporting rod; and a polishing direct current (DC) power supply respectively connected to contacts of the anode disc supporting rod and the cathode disc supporting rod by virtue of wires. The cathode disc supporting rod is provided with a polishing liquid injection assembly.

A polishing process implemented on the basis of the polishing device for an indium phosphide substrate includes the following steps:
step (1): putting an indium phosphide substrate into a substrate slot of the planet gear;
step (2): by virtue of the cathode lifting mechanism, enabling the polishing cloth positioned on the lower end surface of the cathode disc to contact the indium phosphide substrate, and keeping a polishing pressure between the cathode disc and the graphite electrode plate within a range of 40-400 g/cm²;
step (3): injecting the electrolyte into the electrolyzer through the polishing liquid injection assembly until the electrolyte immerses the cathode disc;
step (4): driving, by virtue of the anode rotation driving mechanism and the cathode rotation driving mechanism, the cathode disc and the graphite electrode plate to rotate according to opposite directions, and at the same time, starting to inject polishing liquid through the polishing liquid injection assembly; and after the cathode disc and the graphite electrode plate rotate for 2-3 min, initiating an agitator, turning on the polishing DC power supply, and opening a stop valve of an electrolyte discharge pipe;
step (5): after 9-12 min, turning off the polishing DC power supply and shutting down the driving of the anode rotation driving mechanism and the cathode rotation driving mechanism; separating the cathode disc from the graphite electrode plate by virtue of the cathode lifting mechanism; positioning the indium phosphide substrate above a liquid level of the electrolyte by virtue of the anode lifting mechanism; and taking out the indium phosphide substrate;
step (6): testing the roughness of a surface of the indium phosphide substrate facing to an anode;
when the roughness cannot meet a requirement, putting the indium phosphide substrate into the substrate slot in statu quo, and repeating the steps (2), (4) and (5); and when the roughness meets the requirement, reversing the indium phosphide substrate, putting the same into the substrate slot, and repeating the steps (2), (4) and (5);
step (7): after polishing of both sides of the indium phosphide substrate is completed, stopping the polishing liquid injection assembly from injecting the polishing liquid and the electrolyte, stopping the motion of the agitator, and emptying the electrolyte; and step (8): cleaning, drying and packaging the indium phosphide substrate that meets a polishing requirement.

Beneficial effects achieved in the present invention: By the adoption of the method integrating mechanical polishing and chemical polishing, the roughness of a polished surface of the indium phosphide substrate can reach 0.3 nm. In the present invention, selection ranges of the electrolyte and the polishing liquid can be changed. The low-cost electrolyte and polishing liquid can meet the technical requirements and achieve the polishing effect, and the production cost is greatly saved.

### BRIEF DESCRIPTION OF THE DRAWINGS

FIG. 1 is a schematic structural diagram of the present invention;

FIG. 2 is a schematic diagram of assembling of a planet gear and an intermediate driving mechanism;

FIG. 3 is a schematic diagram of a planet gear; and

FIG. 4 is a schematic diagram of polishing cloth positioned on a lower end surface of the cathode disc.

In the drawings: 1: cathode disc; 1-1: polishing liquid injection branch pipe; 2: gear; 3: electrolyzer; 4: agitator; 5: indium phosphide substrate; 6: electrolyte; 7: anode disc; 8: anode disc supporting rod; 8-1: anode disc rotation snap ring; 9: graphite electrode plate; 10: fixing bolt; 11: anode polishing cloth clamp; 12: electrolyte discharge pipe; 13: polishing cloth; 13-1: feeding hole; 13-2: gear hole; 14: internal gear; 14-1: fixed clamp; 15: wire; 16: cathode disc supporting rod; 16-1: polishing liquid injection branch pipe; 16-2: slurry pipe; 16-3: electrolyte injection pipe; 17: planet gear; 17-1: substrate slot; 17-2: air guide hole; 18: cathode polishing cloth clamp; 19: fixing rod; 20: polishing DC power supply; 21: gear shaft; 21-1: key; 31: cathode guide column; 31-1: base; 31-2: connection column; 32: cathode guide drive; 32-1: cathode supporting table; 32-2: cathode rotation driving mechanism; 32-3: cathode disc snap ring arm; 32-4: fixing ring arm; 33: anode guide drive; 33-1: anode supporting table; 33-2: anode rotation driving mechanism; 33-3: gear shaft driving arm; 33-4: anode disc snap ring arm; 33-5: gear shaft drive; and 34: anode guide column.

### DETAILED DESCRIPTION OF THE INVENTION

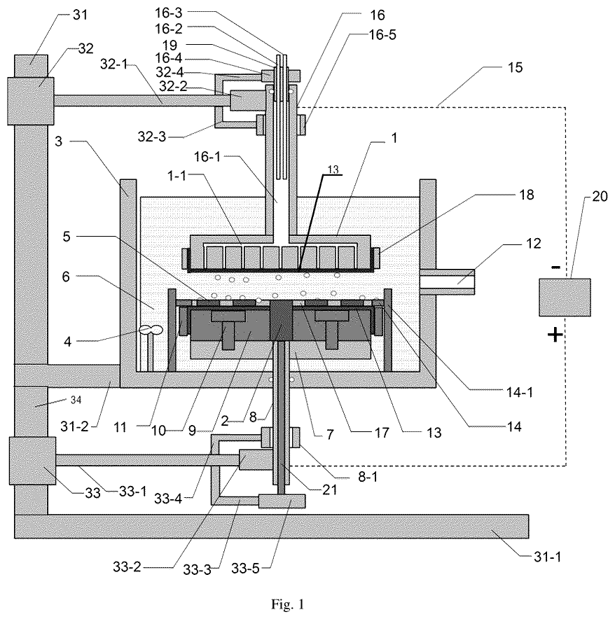

Referring to FIG. 1, a polishing device for an indium phosphide substrate of the present invention includes an electrolyzer 3; an anode disc supporting rod 8 positioned at a center position of a bottom of the electrolyzer 3 by virtue of an anode lifting mechanism; an anode disc 7 hinged to an upper end of the anode disc supporting rod 8; a cathode disc supporting rod 16 positioned above the anode disc 7 by virtue of a cathode lifting mechanism; a cathode disc 1 arranged at a lower end of the cathode disc supporting rod 16; polishing cloth 13 positioned on a lower end surface of the cathode disc 1 by virtue of a cathode polishing cloth clamp 18; a graphite electrode plate 9 arranged on the anode disc 7 by virtue of a connection mechanism; a group of planet gears 17 arranged on an upper end surface of the graphite electrode plate 9 by virtue of an intermediate driving mechanism; polishing cloth 13 positioned between the graphite electrode plate 9 and the planet gear 17 by virtue of an anode polishing cloth clamp 11; an anode rotation driving mechanism connected to the intermediate driving mechanism; a cathode rotation driving mechanism connected to the cathode disc supporting rod 16; and a polishing DC power supply 20 respectively connected to contacts of the anode disc supporting rod 8 and the cathode disc supporting rod 16 by virtue of wires. The cathode disc supporting rod 16 is provided with a polishing liquid injection assembly. The connection mechanism is a fixing bolt 10.

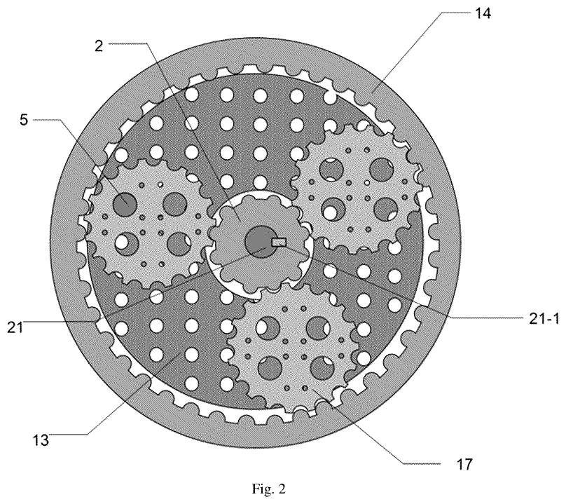

Referring to FIG. 2, the intermediate driving mechanism includes a gear shaft 21 which is arranged in the anode disc supporting rod 8, a gear 2 which is connected to the gear shaft 21 and is positioned at a center axis of the graphite electrode plate 9, and an internal gear 14 which is positioned on the upper end surface of the graphite electrode plate 9 by virtue of a fixed clamp 14-1; the planet gear 17 is meshed between the internal gear 14 and the gear 2; and a lower end of the gear shaft 21 is connected to the anode rotation driving mechanism. The gear shaft 21 and the gear 2 are connected through a key 21-1.

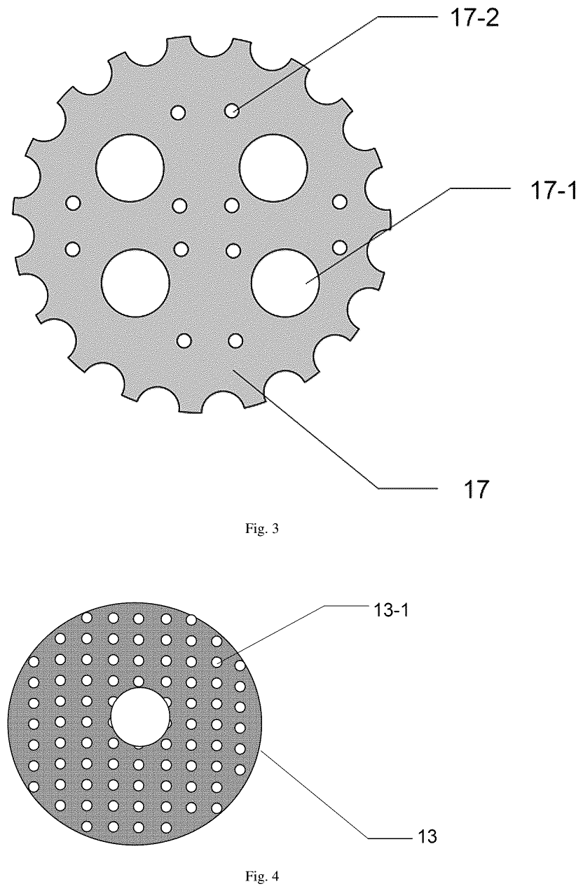

Referring to FIG. 3, a group of substrate slots 17-1 and a group of air guide holes 17-2 are formed in the planet gear 17. An electrolyte discharge pipe 12 with a stop valve is arranged at a middle position of a side part of the electrolyzer 3. An inner bottom of the electrolyzer 3 is provided with an agitator 4. A surface layer of each of the anode disc supporting rod 8 and the cathode disc supporting rod 16 is provided with a ceramic protection layer and an anti-acid paint layer in sequence from inside to outside. A surface layer of each of the anode disc 7 that contacts the electrolyte is provided with a ceramic protection layer and an anti-acid paint layer. There are no ceramic protection layer and no anti-acid paint layer between the anode disc 7 and the graphite electrode plate 9, and the anode disc 7 directly contacts the graphite electrode plate 9. Graphite paper is placed between the anode disc 7 and the graphite electrode plate 9, and is pressed by the fixing bolt 10 to prevent the electrolyte from entering their contact surfaces and also achieve a good conductive effect.

Referring to FIG. 1, the internal gear 14 is assembled on the fixed clamp 14-1 and is fixed at the bottom of the electrolyzer 3. The graphite electrode plate 9 and the anode disc 7 are fixed together through the fixing bolt 10. The gear shaft 21 is assembled inside the anode disc supporting rod 8. The anode disc 7 is fixed on the anode disc supporting rod 8, and the gear 2 is assembled on the gear shaft 21. The anode disc supporting rod 8 is threaded through an anode disc rotation snap ring 8-1 and fixed to the anode rotation driving mechanism. The gear shaft 21 is assembled onto a gear shaft drive 33-5. The polishing cloth 13 is fixed on the graphite electrode plate 9 through the anode polishing cloth clamp 11. The planet gear 17 is placed on the anode polishing cloth 13, and is in fit with the internal gear 14 and gear 2.

Referring to FIG. 1 and FIG. 4, the polishing liquid injection assembly includes a polishing liquid injection main pipe 16-1 arranged in the cathode disc supporting rod 16, and a group of polishing liquid injection branch pipes 1-1 which is connected to the polishing liquid injection main pipe 16-1 and is disposed in the cathode disc 1; an upper end of the polishing liquid injection main pipe 16-1 is respectively provided with a slurry pipe 16-2 and an electrolyte injection pipe 16-3. A feeding hole 13-1 matched with an outlet of the polishing liquid injection branch pipe 1-1 is formed in the polishing cloth 13 positioned on the lower end surface of the cathode disc 1. The slurry pipe 16-2 and the electrolyte injection pipe 16-3 are assembled together by virtue of the fixing rod 19, and then the fixing rod 19 is fixed in the polishing liquid injection pipe 16-1 by a rubber ring; the cathode disc supporting rod 16 is threaded through an upper disc rotation snap ring 16-5 and is assembled on the cathode rotation driving mechanism to ensure that the cathode disc 1 steadily rotates. An upper end of the fixing rod 19 is mounted on a fixing ring 16-4 for fixing the slurry pipe 16-2 and the electrolyte injection pipe 16-3. The fixing ring 16-4 is connected with the cathode supporting table 32-1 through a fixing ring arm 32-4 to ensure that the slurry pipe 16-2 and the electrolyte injection pipe 16-3 are stationary during the rotation of the cathode disc supporting rod 16 and to stabilize liquid supplying. The cathode disc supporting rod 16 and the cathode disc 1 are assembled together. The internal polishing liquid injection main pipe 16-1 cooperates with the polishing liquid injection branch pipe 1-1, and the polishing cloth 13 is fixed on the cathode disc 1 by using the cathode polishing cloth clamp 18.

Referring to FIG. 1, the anode lifting mechanism and the cathode lifting mechanism are connected with the electrolyzer 3 by virtue of a connection column 31-2; the cathode lifting mechanism includes a cathode guide column 31 which is arranged on a side part of the electrolyzer 3 by virtue of the connection column 31-2, and the cathode supporting table 32-1 which is arranged on the cathode guide column 31 by virtue of the cathode guide drive 32; the cathode supporting table 32-1 is connected to the cathode disc supporting rod 16; the anode lifting mechanism includes an anode guide column 34 which is arranged below the side part of the electrolyzer 3 by virtue of a base 31-1 and the connection column 31-2, and an anode supporting table 33-1 which is arranged on the anode guide column 34 by virtue of the anode guide drive 33; and the anode supporting table 33-1 is connected to the anode disc supporting rod 8.

Referring to FIG. 1, the upper disc rotating snap ring 16-5 is connected to the cathode supporting table 32-1 through a cathode disc snap ring arm 32-3. The cathode rotation driving mechanism is directly connected to the cathode supporting table 32-1. The cathode supporting table 32-1 is connected to the cathode guide drive 32 to realize up and down movement of an entire cathode. The anode disc rotating snap ring 8-1 is connected to the anode supporting table 33-1 through an anode disc snap ring arm 33-4. The cathode rotation driving mechanism is directly connected to the anode supporting table 33-1. A gear shaft drive 33-5 is connected to the anode supporting table 33-1 through a gear shaft driving arm 33-3. The anode supporting table 33-1 is connected to the anode guide drive 33 to realize up and down movement of an entire anode.

The mechanism of action of the present invention is as follows: In neutral or weakly acidic electrolyte such as sodium chloride and potassium chloride, the graphite electrode plate 9 is used as a cathode placed in the electrolyzer 3. During electrochemical polishing, the porous polishing cloth 13 is arranged on the graphite electrode plate 9. At the same time, an anode is disposed in the electrolyzer 3. The indium phosphide substrate is electrochemically polished through the porous polishing cloth 13 and chlorine gas generated by electrolysis. In this process, aluminium oxide or silicon dioxide slurry can also be placed into the electrolyzer 3 to achieve mechanical polishing of the indium phosphide substrate.

The polishing slurry and the electrolyte are sent to the middle of a polishing disc together for polishing. In the polishing process, the polishing disc is used as an electrode, and electrochemical reactions occur: cathode reaction: 2H⁺+2e→H₂(g); anode reaction: 2Cl⁻−2e→Cl₂(g); reaction between the generated chlorine gas and the indium phosphide substrate: Cl₂+In—P→In—Cl+P—Cl. At the same time, due to the mechanical grinding effect of the polishing slurry, electrochemical and mechanical dual-polishing of the indium phosphide substrate is realized.

A polishing process of the present invention includes the following steps:
step (1): the indium phosphide substrate 5 is put into the substrate slot 17-1 of the planet gear 17;
step (2): by virtue of the cathode lifting mechanism, the polishing cloth 13 positioned on the lower end surface of the cathode disc 1 is enabled to contact the indium phosphide substrate 5, and a polishing pressure between the cathode disc 1 and the graphite electrode plate 9 is kept within a range of 40-400 g/cm²;
step (3): the electrolyte is injected into the electrolyzer 3 through the polishing liquid injection assembly until the electrolyte immerses the cathode disc 1;
step (4): the cathode disc 1 and the graphite electrode plate 9 are driven, by virtue of the anode rotation driving mechanism and the cathode rotation driving mechanism, to rotate according to opposite directions, and at the same time; polishing liquid is started to be polished through the polishing liquid injection assembly; and after the cathode disc 1 and the graphite electrode plate 9 rotate for 2-3 min, the agitator 4 is initiated; the polishing DC power supply 20 is turned on; and the stop valve of the electrolyte discharge pipe 12 is opened;
step (5): after 9-12 min, the polishing DC power supply 20 is turned off, and the driving of the anode rotation driving mechanism and the cathode rotation driving mechanism are shut down; the cathode disc 1 is separated from the graphite electrode plate 9 by virtue of the cathode lifting mechanism; the indium phosphide substrate 5 is positioned above a liquid level of the electrolyte 6 by virtue of the anode lifting mechanism; and the indium phosphide substrate 5 is taken out;
step (6): the roughness of a surface of the indium phosphide substrate 5 facing to an anode is tested; when the roughness cannot meet a requirement, the indium phosphide substrate is put into the substrate slot 17-1 in statu quo, and the steps (2), (4) and (5) are repeated; and when the roughness meets the requirement, the indium phosphide substrate 5 is reversed, the same is put into the substrate slot 17-1, and the steps (2), (4) and (5) are repeated;
step (7): after polishing of both sides of the indium phosphide substrate 5 is completed, the polishing liquid injection assembly is stopped from injecting the polishing liquid and the electrolyte; the motion of the agitator 4 is stopped; and the electrolyte is emptied; and step (8): the indium phosphide substrate 5 that meets a polishing requirement is cleaned, dried, and packaged.

The specific polishing process of the present invention is as follows: The indium phosphide substrate 5 is put into the substrate slot 17-1. The electrolyte is injected into the electrolyzer 3 until the electrolyte can immerse the cathode disc 1. The cathode disc 1 is lowered until the polishing cloth 13 contacts the indium phosphide substrate 5. The cathode disc 1 and the anode disc 7 rotate according to opposite directions through the cathode supporting rod 16 and the anode supporting rod 8. At the same time, the polishing liquid is injected into the polishing liquid injection main pipe 16-1 through the slurry pipe 16-2 and the electrolyte injection pipe 16-3, is then sent to the polishing cloth 13 through the polishing liquid injection branch pipe 1-2, and enters the indium phosphide substrate 5 and the graphite electrode plate 9 through the feeding hole 13-1 in the polishing cloth 13. After the cathode disc 1 and the anode disc 7 rotate for 2-3 min, the DC power supply 20 is turned on to start electrochemical and mechanical polishing. At the same time, the agitator 4 is initiated, and the electrolyte discharge pipe 12 is opened. In the polishing process, after a period of time, the polishing DC power supply 20 is turned off, and the cathode disc 1 and the anode polishing disc 7 are stopped from rotating; and the cathode disc 1 and the anode polishing disc 7 are separated. The cathode supporting rod 8 and the anode supporting rod 16 are raised, so that the indium phosphide substrate 5 is located above the liquid level of the electrolyte; and the indium phosphide substrate 5 is taken out to test the polishing state. When the surface of the indium phosphide substrate 5 facing to the anode side is polished to the required roughness, the indium phosphide substrate 5 is reversed, and the above steps are repeated to start to polish the other side surface. After the polishing is completed, the injection of the slurry and the electrolyte to the slurry pipe 16-2 and the electrolyte injection pipe 16-3 is stopped, and the electrolyte discharge pipe 12 is closed. The rotations of the cathode disc 1 and the anode polishing disc 7 are stopped. The cathode disc 1 is lifted up; the motion of the agitator 4 is stopped; the electrolyte is emptied; and the indium phosphide substrate 5 is taken out and is then cleaned, dried and packaged.

1. A polishing device for an indium phosphide substrate, characterized by comprising an electrolyzer (3), wherein the polishing device further comprises an anode disc supporting rod (8) positioned at a center position of a bottom of the electrolyzer (3) by virtue of an anode lifting mechanism; an anode disc (7) hinged to an upper end of the anode disc supporting rod (8); a cathode disc supporting rod (16) positioned above the anode disc (7) by virtue of a cathode lifting mechanism; a cathode disc (1) arranged at a lower end of the cathode disc supporting rod (16); polishing cloth (13) positioned on a lower end surface of the cathode disc (1) by virtue of a cathode polishing cloth clamp (18); a graphite electrode plate (9) arranged on the anode disc (7) by virtue of a connection mechanism; a group of planet gears (17) arranged on an upper end surface of the graphite electrode plate (9) by virtue of an intermediate driving mechanism; polishing cloth (13) positioned between the graphite electrode plate (9) and the planet gear (17) by virtue of an anode polishing cloth clamp (11); an anode rotation driving mechanism connected to the intermediate driving mechanism; a cathode rotation driving mechanism connected to the cathode disc supporting rod (16); and a polishing direct current (DC) power supply (20) respectively connected to contacts of the anode disc supporting rod (8) and the cathode disc supporting rod (16) by virtue of wires; and the cathode disc supporting rod (16) is provided with a polishing liquid injection assembly.

2. The polishing device for the indium phosphide substrate according to claim 1, characterized in that the intermediate driving mechanism comprises a gear shaft (21) which is arranged in the anode disc supporting rod (8), a gear (2) which is connected to the gear shaft (21) and is positioned at a center axis of the graphite electrode plate (9), and an internal gear (14) which is positioned on the upper end surface of the graphite electrode plate (9) by virtue of a fixed clamp (14-1); the planet gear (17) is meshed between the internal gear (14) and the gear (2); and a lower end of the gear shaft (21) is connected to the anode rotation driving mechanism.

3. The polishing device for the indium phosphide substrate according to claim 1, characterized in that the polishing liquid injection assembly comprises a polishing liquid injection main pipe (16-1) arranged in the cathode disc supporting rod (16), and a group of polishing liquid injection branch pipes (1-1) which is connected to the polishing liquid injection main pipe (16-1) and is disposed in the cathode disc (1); an upper end of the polishing liquid injection main pipe (16-1) is respectively provided with a slurry pipe (16-2) and an electrolyte injection pipe (16-3); and a feeding hole (13-1) matched with an outlet of the polishing liquid injection branch pipe (1-1) is formed in the polishing cloth (13) positioned on the lower end surface of the cathode disc (1).

4. The polishing device for the indium phosphide substrate according to claim 1, characterized in that a group of substrate slots (17-1) and a group of air guide holes (17-2) are formed in the planet gear (17).

5. The polishing device for the indium phosphide substrate according to claim 1, characterized in that an electrolyte discharge pipe (12) with a stop valve is arranged at a middle position of a side part of the electrolyzer (3).

6. The polishing device for the indium phosphide substrate according to claim 1, characterized in that an inner bottom of the electrolyzer (3) is provided with an agitator (4).

7. The polishing device for the indium phosphide substrate according to claim 1, characterized in that a surface layer of each of the anode disc supporting rod (8) and the cathode disc supporting rod (16) is provided with a ceramic protection layer and an anti-acid paint layer in sequence from inside to outside.

8. The polishing device for the indium phosphide substrate according to claim 1, characterized in that the anode lifting mechanism and the cathode lifting mechanism are connected with the electrolyzer (3) by virtue of a connection column (31-2); the cathode lifting mechanism comprises a cathode guide column (31) which is arranged on a side part of the electrolyzer (3) by virtue of the connection column (31-2), and a cathode supporting table (32-1) which is arranged on the cathode guide column (31) by virtue of a cathode guide drive (32); the cathode supporting table (32-1) is connected to the cathode disc supporting rod (16); the anode lifting mechanism comprises an anode guide column (34) which is arranged below the side part of the electrolyzer (3) by virtue of a base (31-1) and the connection column (31-2), and an anode supporting table (33-1) which is arranged on the anode guide column (34) by virtue of the anode guide drive (33); and the anode supporting table (33-1) is connected to the anode disc supporting rod (8).

9. A polishing process for an indium phosphide substrate, which is implemented on the basis of the polishing device for an indium phosphide substrate, characterized in that the polishing process comprises the following steps:
step (1): putting an indium phosphide substrate (5) into a substrate slot (17-1) of the planet gear (17-1);
step (2): by virtue of the cathode lifting mechanism, enabling the polishing cloth (13) positioned on the lower end surface of the cathode disc (1) to contact the indium phosphide substrate (5), and keeping a polishing pressure between the cathode disc (1) and the graphite electrode plate (9) within a range of 40-400 g/cm²;
step (3): injecting the electrolyte into the electrolyzer (3) through the polishing liquid injection assembly until the electrolyte immerses the cathode disc (1);
step (4): driving, by virtue of the anode rotation driving mechanism and the cathode rotation driving mechanism, the cathode disc (1) and the graphite electrode plate (9) to rotate according to opposite directions, and at the same time, starting to inject polishing liquid through the polishing liquid injection assembly; and after the cathode disc (1) and the graphite electrode plate rotate (9) for 2-3 min, initiating the agitator (4), turning on the polishing DC power supply (20), and opening the stop valve of the electrolyte discharge pipe (12);
step (5): after 9-12 min, turning off the polishing DC power supply (20) and shutting down the driving of the anode rotation driving mechanism and the cathode rotation driving mechanism;
separating the cathode disc (1) from the graphite electrode plate (9) by virtue of the cathode lifting mechanism; positioning the indium phosphide substrate (5) above a liquid level of the electrolyte (6) by virtue of the anode lifting mechanism; and taking out the indium phosphide substrate (5);
step (6): testing the roughness of a surface of the indium phosphide substrate (5) facing to an anode; when the roughness cannot meet a requirement, putting the indium phosphide substrate (5) into the substrate slot (17-1) in statu quo, and repeating the steps (2), (4) and (5); and when the roughness meets the requirement, reversing the indium phosphide substrate (5), putting the same into the substrate slot (17-1), and repeating the steps (2), (4) and (5);
step (7): after polishing of both sides of the indium phosphide substrate (5) is completed, stopping the polishing liquid injection assembly from injecting the polishing liquid and the electrolyte, stopping the motion of the agitator (4), and emptying the electrolyte; and
step (8): cleaning, drying and packaging the indium phosphide substrate (5) that meets a polishing requirement.
